(19) United States
(12) Patent Application Publication
(10) Pub. No.: US 2009/0148975 A1
(43) Pub. Date: Jun. 11, 2009

(54) Method of manufacturing nitride semiconductor device

(75) Inventor: Shinichi Kohda, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/078,063

(22) Filed: Mar. 26, 2008

(30) Foreign Application Priority Data
Mar. 27, 2007 (JP) 2007-82310

(51) Int. Cl. H01L 21/268

(52) U.S. Cl. 438/33; 257/E21.349

(57) ABSTRACT

A method of manufacturing a nitride semiconductor device includes: a working region forming step of forming a working region in a group III nitride semiconductor substrate by converging a laser beam having a wavelength of 500 nm to 700 nm in the group III nitride semiconductor substrate and by scanning a convergent point of the laser beam in a prescribed scanning direction in the interior of the group III nitride semiconductor substrate; and a dividing step of dividing the group III nitride semiconductor substrate by generating a crack from the working region without processing a surface of the group III nitride semiconductor substrate.

### BACKGROUND OF THE INVENTION

1. Field of the Invention

The present invention relates to a method of manufacturing a nitride semiconductor device employing a group III nitride semiconductor.

2. Description of Related Art

Conventionally, a semiconductor device (such as an LED, an LD or a transistor, for example) is formed from a nitride semiconductor substrate made of a group III nitride semiconductor such as aluminum nitride (AlN), gallium nitride (GaN) or indium nitride (InN) in each device size (chip size).

In order to form the semiconductor device from the nitride semiconductor substrate, the surface of a wafer shaped nitride semiconductor substrate on which a semiconductor layer made of GaN, for example, is laminated is scribed with a diamond cutter or the like along a scribe line, and external force is applied to the scribed part to cleave the substrate.

However, the nitride semiconductor substrate is inferior in cleavage feature that it is difficult to correctly cleave the substrate along the cleavage plane thereof.

Therefore, a method has been proposed for making the substrate easily crackable (cleavable) along the cleavage plane by a laser beam absorption at the surface of the substrate for melting the substrate material or generating small cracks by a thermal impact, thereby forming a trench on the surface of the substrate.

Another method has also been proposed for making the substrate easily crackable (cleavable) by grinding the surface of the substrate with a diamond cutter, thereby forming a trench.

In each of the methods, however, debris (dust) may scatter to adhere to the surface of the substrate when the trench is formed on the surface of the substrate. In the former method of forming the trench by introducing the laser beam into the surface of the substrate, the substrate may be heated by the laser beam.

Therefore, the device characteristics of the manufactured semiconductor device may be deteriorated due to adhesion of debris (dust) to the surface of the substrate or a temperature rise in the substrate. If debris (dust) adhere to a resonance cavity end face of an LD or the like, for example, light may be scattered or the reflectance of the resonance cavity end face may be reduced due to the debris (dust).

### SUMMARY OF THE INVENTION

An object of the present invention is to provide a method of manufacturing a nitride semiconductor device capable of stably cleaving a group III nitride semiconductor substrate and suppressing formation of debris (dust) in cleavage.

Another object of the present invention is to provide a method of manufacturing a nitride semiconductor device capable of stably cleaving a group III nitride semiconductor substrate and suppressing a temperature rise in the substrate in cleavage.

A method of manufacturing a nitride semiconductor device of the present invention includes a working region forming step of forming a working region in a group III nitride semiconductor substrate by converging a laser beam having a wavelength of 500 nm to 700 nm in the group III nitride semiconductor substrate and by scanning a convergent point of the laser beam in a prescribed scanning direction in the interior of the group III nitride semiconductor substrate; and a dividing step of dividing the group III nitride semiconductor substrate by generating a crack from the working region without processing a surface of the group III nitride semiconductor substrate.

According to this method, the laser beam having a wavelength of 500 nm to 700 nm not absorbed into the group III nitride semiconductor is converged in the group III nitride semiconductor substrate, to generate multiphoton absorption on the convergent point.

The convergent point is scanned in the prescribed scanning direction, so that the working region is formed in the group III nitride semiconductor substrate due to the multiphoton absorption.

After the working region is formed, the group III nitride semiconductor substrate is divided by generating a crack from the working region without processing the surface of the group III nitride semiconductor substrate. Thus, a nitride semiconductor device made of the group III nitride semiconductor divided into a device size (chip size) is obtained.

As hereinabove described, the working region is formed in the substrate due to the multiphoton absorption, whereby a deep crack can be generated from this working region. Therefore, the group III nitride semiconductor substrate can be stably cleaved, and a nitride semiconductor device having an excellent cleavage plane can be obtained.

When the group III nitride semiconductor substrate is cleaved (divided), the surface of the group III nitride semiconductor substrate is not processed, whereby formation of debris (dust) can be suppressed in cleavage of the group III nitride semiconductor substrate. Further, the method to form the working region is not to make a laser beam absorption in the group III nitride semiconductor substrate to treat with heat of the absorbed laser beam, but to converge the laser beam of a small energy in the group III nitride semiconductor substrate and generate multiphoton absorption for processing. Therefore, the group III nitride semiconductor substrate can be prevented from a temperature rise in cleavage. Consequently, the nitride semiconductor device can be prevented from deterioration of the device characteristics. Further, the shape of the nitride semiconductor device can be stabilized and the yield thereof can be improved, while minimizing damages on the group III nitride semiconductor substrate.

The working region forming step may include a step of forming a plurality of working regions at a prescribed interval. For example, the working region forming step may include a step of forming a plurality of short working regions by reducing the scanning distance of the laser beam per working region.

More specifically, the plurality of working regions may be formed in the form of perforations at an interval along the scanning direction.

The working regions are formed by multiphoton absorption of the laser beam, even if each working region is small, deep cracks can be generated from the small working regions. Therefore, the group III nitride semiconductor substrate can be stably cleaved.

Preferably, the working region forming step includes a step of forming the working region on a position having a depth of 10 μm or more from the surface of the group III nitride semiconductor substrate. When the working region is formed on the position having a depth of 10 μm or more from the surface of the group III nitride semiconductor substrate, the group III nitride semiconductor substrate can be more stably cleaved.

Preferably, the working region forming step includes the steps of forming a first working region on a position having a first depth from the surface of the group III nitride semiconductor substrate; and forming a second working region on a position having a second depth different from the first depth.

According to this method, a plurality of (at least two) working regions having different depths from the surface of the group III nitride semiconductor substrate are formed in the group III nitride semiconductor substrate. Even if the group III nitride semiconductor substrate is bent or uneven in thickness, the group III nitride semiconductor substrate can be stably cleaved when one of the plurality of working regions is formed in a depth optimum for cleaving the group III nitride semiconductor substrate.

The working region forming step may further include a step of forming at least one working region on a position displaced from the working region in the scanning direction and having a depth different from the depth of the working region from the surface of the group III nitride semiconductor substrate. In other words, the plurality of working regions having different depths from the surface of the group III nitride semiconductor substrate need not be aligned in the depth direction, but may be formed on positions displaced from each other along the main surface of the substrate.

Preferably, the working region forming step further includes a step of further forming a working region overlapping a working start position of the working region after forming the working region by scanning the convergent point of the laser beam oppositely to the scanning direction from a second working start position which is an intermediate portion between the working start position and a working end position of the working region.

According to this method, the working region is formed in advance, and the additional working region is further formed from the second working start position which is an intermediate portion of the previously formed working region to overlap the working start position of the previously formed working region.

In other words, the additional working region is further formed on the same scanning line as the previously formed working region.

Thus, the two working regions are formed into a composite working region, and both ends of the composite working region correspond to the working end positions for the respective working regions.

Generally on a scanning end position of a laser beam, the output of a laser unit emitting the laser beam is stable to perform more stable processing as compared with a scanning start position. In other words, according to this method, stable working regions are formed on both ends of the working region, whereby the group III nitride semiconductor substrate can be more stably cleaved.

Preferably, the group III nitride semiconductor substrate has a semiconductor laser structure including a first layer of a first conductivity type, an emission layer laminated on the first layer and a second layer of a second conductivity type different from the first conductivity type laminated on the emission layer, and the working region forming step includes a step of forming the working region by scanning the convergent point of the laser beam in a direction orthogonal to an optical waveguide in the semiconductor laser structure.

According to this method, the working region is formed in the direction orthogonal to the optical waveguide of the semiconductor laser structure, whereby a semiconductor laser structure having an excellent resonance cavity end face (mirror face) formed of a cleavage plane can be obtained by cleaving the group III nitride semiconductor substrate.

The foregoing and other objects, features and effects of the present invention will become more apparent from the following detailed description of the embodiments with reference to the attached drawings.

### BRIEF DESCRIPTION OF THE DRAWINGS

FIG. 1 is a perspective view for illustrating the structure of a semiconductor laser diode manufactured by a method according to the present invention.

FIG. 2 is a longitudinal sectional view taken along the line II-II in FIG. 1.

FIG. 3 is a transverse sectional view taken along the line III-III in FIG. 1.

FIG. 4 is a perspective view of a GaN single-crystalline wafer constituting a GaN single-crystalline substrate shown in FIG. 1, in a state formed with individual devices.

FIG. 5A is an illustrative diagram for illustrating a method of cleaving into the individual devices (first embodiment), showing a step of forming working regions in individual devices.

FIG. 5B is an illustrative diagram for illustrating the method of cleaving into the individual devices (first embodiment), showing a step of dividing into individual devices.

FIG. 6A is an illustrative diagram for illustrating another method of cleaving into the individual devices (second embodiment), showing a step of forming working regions in individual devices.

FIG. 6B is an illustrative diagram for illustrating the method of cleaving into individual devices (second embodiment), showing a step of dividing into individual devices.

FIGS. 7A and 7B are illustrative diagrams for illustrating still another method of cleaving into the individual devices (third embodiment), showing a step of forming working regions in individual devices.

FIG. 7C is an illustrative diagram for illustrating the method of cleaving into the individual devices (third embodiment), showing a step of dividing into individual devices.

FIG. 7D is an enlarged view of a working region shown in FIG. 7A.

FIG. 7E is an enlarged view of a working region shown in FIGS. 7B and 7C.

### DETAILED DESCRIPTION OF PREFERRED EMBODIMENTS

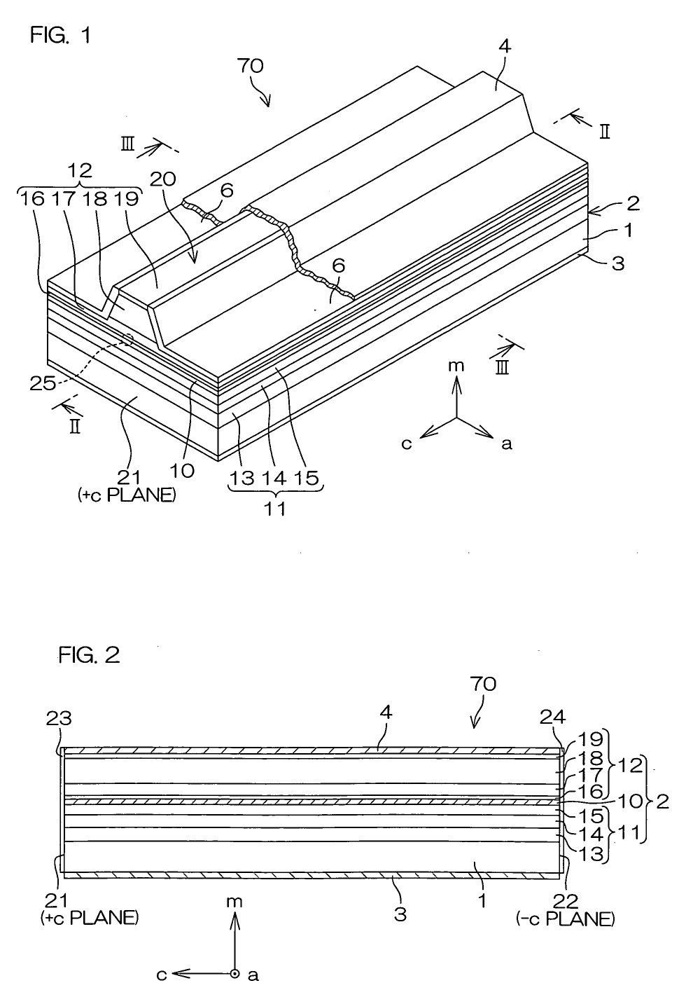

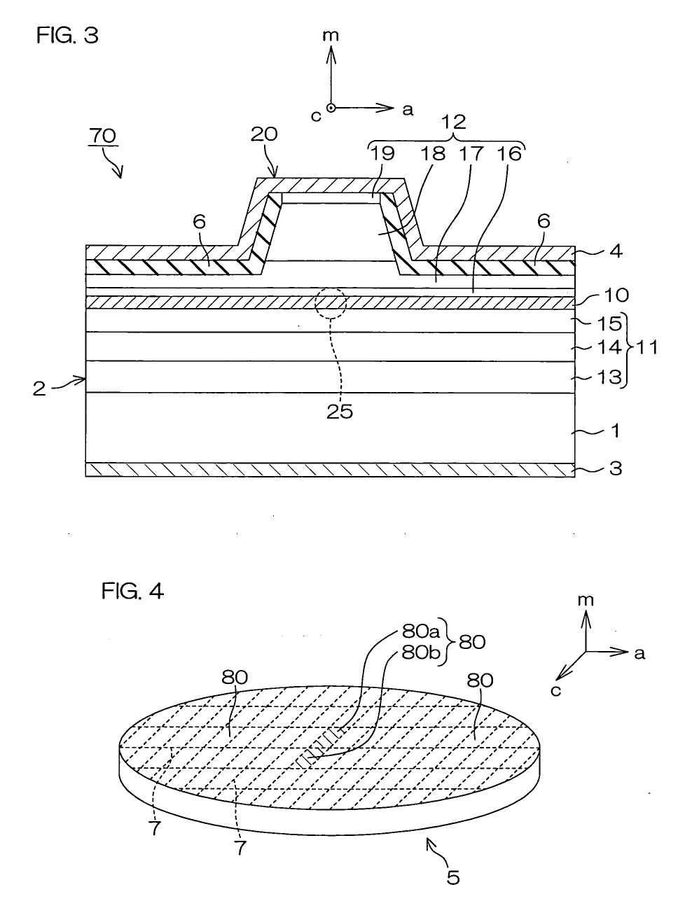

FIG. 1 is a perspective view for illustrating the structure of a semiconductor laser diode manufactured by a method according to an embodiment of the present invention, FIG. 2 is a longitudinal sectional view taken along the line II-II in FIG. 1, and FIG. 3 is a transverse sectional view taken along the line III-III in FIG. 1. Referring to FIGS. 1 to 3, arrows c, m and a denote the c-axis direction, the m-axis direction and the a-axis direction respectively.

This semiconductor laser diode 70 is a Fabry-Perot laser diode including a substrate 1, a group III nitride semiconductor laminate layer 2 formed on the substrate 1 by crystal growth, an n-side electrode 3 formed to come into contact with the rear surface (opposite surface to the group III nitride semiconductor laminate layer 2) of the substrate 1, and a p-side electrode 4 formed to come into contact with the surface of the group III nitride semiconductor laminate layer 2.

The substrate 1 is made of a GaN single-crystalline substrate in this embodiment. The substrate 1 has a nonpolar surface as the main surface for example, and the nonpolar surface is the a-plane or the m-plane. The group III nitride semiconductor laminate layer 2 is formed by crystal growth on this main surface. Therefore, the group III nitride semiconductor laminate layer 2 is made of a group III nitride semiconductor having a nonpolar surface as a crystal growth surface. The size of the substrate 1 has a length of 250 μm to 600 μm in the c-axis direction (parallel to the a-plane) and a length of 200 μm to 400 μm in the a-axis direction (parallel to the c-plane), for example.

The group III nitride semiconductor laminate layer 2 includes an emission layer 10, an n-type semiconductor layer 11 (a first layer of a first conductivity type) and a p-type semiconductor layer 12 (a second layer of a second conductivity type). The n-type semiconductor layer 11 is arranged closer to the substrate 1 with respect to the emission layer 10, while the p-type semiconductor layer 12 is arranged closer to the p-side electrode 4 with respect to the emission layer 10. Thus, the n-type semiconductor layer 11 and the p-type semiconductor layer 12 sandwich the emission layer 10 therebetween to form a double heterojunction. Electrons and holes are injected into the emission layer 10 from the n-type semiconductor layer 11 and the p-type semiconductor layer 12 respectively. The electrons and the holes are recombined with each other in the emission layer 10 to emit light.

The n-type semiconductor layer 11 is configured by laminating an n-type GaN contact layer 13 (having a thickness of 2 μm, for example), an n-type AlGaN clad layer 14 (having a thickness of 1.5 μm or less, for example, 1.0 μm) and an n-type GaN guide layer 15 (having a thickness of 0.1 μm, for example) successively from the side closer to the substrate 1. On the other hand, the p-type semiconductor layer 12 is configured by successively laminating a p-type AlGaN electron block layer 16 (having a thickness of 20 nm, for example), a p-type GaN guide layer 17 (having a thickness of 0.1 μm, for example), a p-type AlGaN clad layer 18 (having a thickness of 1.5 μm or less, for example, 0.4 μm) and a p-type GaN contact layer 19 (having a thickness of 0.3 μm, for example) on the emission layer 10.

The n-type GaN contact layer 13 and the p-type GaN contact layer 19 are low-resistance layers for ohmic contact with the n-side electrode 3 and the p-side electrode 4 respectively. The n-type GaN contact layer 13 is an n-type semiconductor prepared by doping GaN with Si as an n-type dopant, for example, in a high concentration (the doping concentration is 3×10¹⁸ cm⁻³, for example). The p-type GaN contact layer 19 is a p-type semiconductor prepared by doping GaN with Mg as a p-type dopant in a high concentration (the doping concentration is 3×10¹⁹ cm⁻³, for example).

The n-type AlGaN clad layer 14 and the p-type AlGaN clad layer 18 produce a light confinement effect of confining the light emitted from the emission layer 10 therebetween. The n-type AlGaN clad layer 14 is an n-type semiconductor prepared by doping AlGaN with Si as an n-type dopant, for example (the doping concentration is 1×10¹⁸ cm⁻³, for example). The p-type AlGaN clad layer 18 is a p-type semiconductor prepared by doping AlGaN with Mg as a p-type dopant (the doping concentration is 1×10¹⁹ cm⁻³, for example).

The n-type GaN guide layer 15 and the p-type GaN guide layer 17 are semiconductor layers to produce a carrier confinement effect for confining carriers (electrons and holes) in the emission layer 10. Thus, the efficiency in recombination of the electrons and holes in the emission layer 10 is enhanced. The n-type GaN guide layer 15 is an n-type semiconductor prepared by doping GaN with Si as an n-type dopant, for example (the doping concentration is 1×10¹⁸ cm⁻³, for example), and the p-type GaN guide layer 17 is a p-type semiconductor prepared by doping GaN with Mg as a p-type dopant (the doping concentration is 5×10¹⁸ cm³, for example).

The p-type AlGaN electron block layer 16 is a p-type semiconductor prepared by doping AlGaN with Mg as a p-type dopant, for example (the doping concentration is 5×10¹⁸ cm³, for example) to prevent the electrons from flowing out from the emission layer 10 and enhance the efficiency in recombination of the electrons and holes.

The emission layer 10 has an MQW (multiple-quantum well) structure containing InGaN, for example, and is a layer for amplifying light generated by the recombination of the electrons and the holes. More specifically, the emission layer 10 is formed by alternately and repetitively laminating InGaN layers (each having a thickness of 3 nm, for example) and GaN layers (each having a thickness of 9 nm, for example) for a series of cycles. In this case, the composition ratio of In in each InGaN layer is set to 5% or more, so that the InGaN layer has a relatively small band gap to form a quantum well layer. On the other hand, each GaN layer functions as a barrier layer having a relatively large band gap. For example, the InGaN layers and the GaN layers are alternately and repetitively laminated for two to seven cycles to form the emission layer 10 having an MQW structure. The emission wavelength is set to 400 nm to 550 nm by adjusting the In composition in the quantum well layers (InGaN layers).

The p-type semiconductor layer 12 is partially removed to form a ridge stripe 20. More specifically, the p-type GaN contact layer 19, the p-type AlGaN clad layer 18 and the p-type GaN guide layer 17 are partially removed by etching to form the ridge stripe 20 having a generally trapezoidal shape in transverse-sectional view. This ridge stripe 20 is formed along the c-axis direction.

The group III nitride semiconductor laminate layer 2 has a pair of end faces 21 and 22 formed by cleaving both longitudinal ends of the ridge stripe 20. The pair of end faces 21 and 22 formed by cleavage planes are parallel to each other, and orthogonal to the c-axis. Thus, the n-type GaN guide layer 15, the emission layer 10 and the p-type GaN guide layer 17 form a Fabry-Perot resonance cavity having the end faces 21 and 22 as resonance cavity end faces. The light generated in the emission layer 10 is amplified by stimulated emission, while reciprocating between the resonance cavity end faces 21 and 22. The amplified light is partially output from the device as a laser beam through the resonance cavity end faces 21 and 22.

The n-side electrode 3 and the p-side electrode 4 are made of an Al metal, for example, and brought into ohmic contact with the p-type GaN contact layer 19 and the substrate 1 respectively. Insulating layers 6 covering exposed surfaces of the n-type GaN guide layer 17 and the p-type AlGaN clad layer 18 are provided such that the p-side electrode 4 is in contact only with the p-type GaN contact layer 19 on the top face of the ridge stripe 20.

Thus, a current can be concentrated on the ridge stripe 20, thereby enabling efficient laser oscillation. In the semiconductor laser diode 70, a portion directly under the ridge stripe 20 where the current is concentrated forms a waveguide 25 (optical waveguide) for transmitting the light. In other words, the waveguide 25 is also orthogonal to the resonance cavity end faces 21 and 22 (c-planes), similarly to the ridge stripe 20.

The waveguide 25 is formed to have a width of 1 μm to 2 μm, for example. FIGS. 1 and 3 show the waveguide 25 in an enlarged manner for readily view.

According to this embodiment, the resonance cavity end faces 21 and 22 are the c-planes (+c- and −c-planes). The resonance cavity end face 21 is a +c-axis side end face, for example, and the resonance cavity end face 22 is a −c-axis side end face, for example. In this case, the crystal plane of the resonance cavity end faces 21 is the +c-plane, and that of the resonance cavity end face 22 is the −c-plane.

Insulating films (not shown) different in reflectance from each other are formed on the resonance cavity end faces 21 and 22 respectively. More specifically, an insulating film having a small reflectance is formed on the +c-axis side end face 21, and an insulating film having a large reflectance is formed on the −c-axis side end face 22. Therefore, the +c-axis side end face 21 emits a larger laser output. In other words, the +c-axis side end face 21 is a laser emission face in this semiconductor laser diode 70.

According to this structure, light having a wavelength of 400 nm to 550 nm can be emitted by connecting the n-side electrode 3 and the p-side electrode 4 to a power source and injecting electrons and holes into the emission layer 10 from the n-type semiconductor layer 11 and the p-type semiconductor layer 12 respectively, thereby recombining the electrons and holes in the emission layer 10.

This light is amplified by stimulated emission, while reciprocating between the resonance cavity end faces 21 and 22 along the guide layers 15 and 17. Then, more laser output is extracted from the resonance cavity end face 21 functioning as the laser emission face.

A method of manufacturing the semiconductor laser diode 70 is now described.

In order to manufacture the semiconductor laser diode 70, individual devices 80 (group III nitride semiconductor substrates) each forming the semiconductor laser diode 70 are formed on a GaN single-crystalline wafer 5 forming the GaN single-crystalline substrate 1, as illustratively shown in FIG. 4.

More specifically, the n-type semiconductor layer 11, the emission layer 10 and the p-type semiconductor layer 12 are epitaxially grown on the wafer 5, thereby forming the group III nitride semiconductor laminate layer 2. After the formation of the group III nitride semiconductor laminate layer 2, the ridge stripe 20 is formed by dry etching, for example. Then, the insulating layers 6, the p-side electrode 4 and the n-side electrode 3 are formed. Thus, the wafer 5 formed with the individual devices 80 is obtained.

Scribing lines 7 formed on the wafer 5 partition the wafer 5 into the individual devices 80 in a grid. In other words, the scribing lines 7 are formed along the c-planes and the a-planes of the individual devices 80.

Thereafter the wafer 5 is divided into the individual devices 80. In other words, the wafer 5 is cleaved along the scribing lines 7 to cut out the individual devices 80.

A method of cleaving the wafer 5 into the individual devices 80 is now described with reference to three embodiments.

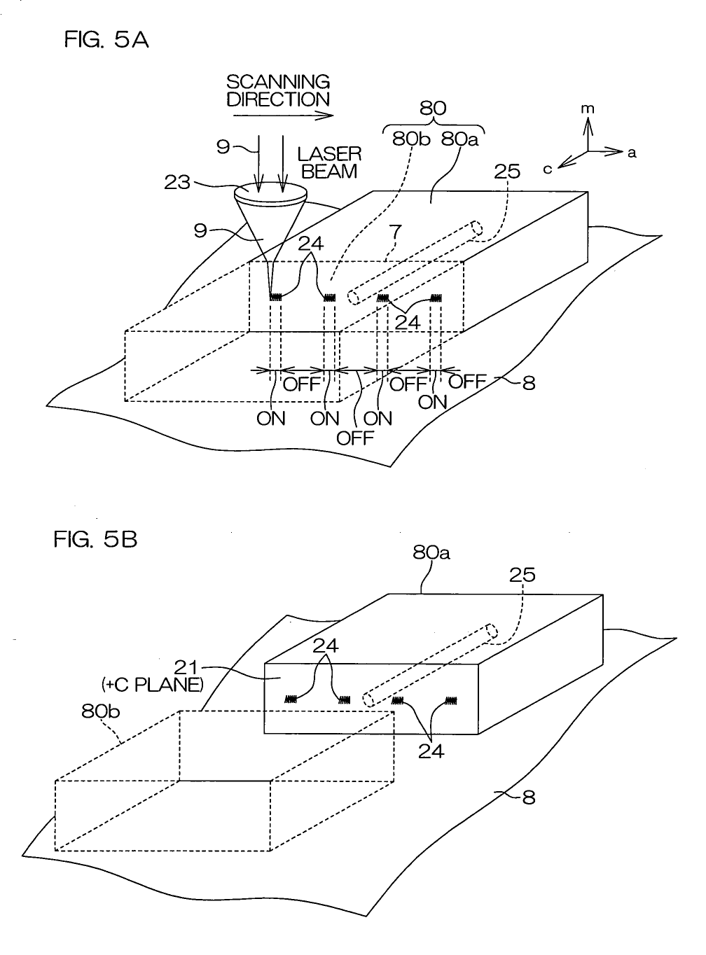

FIGS. 5A and 5B are illustrative diagrams for illustrating a method of cleaving the wafer 5 into the individual devices 80 according to the first embodiment. FIGS. 5A and 5B illustrate only cleaving into individual devices 80a and 80b shown in FIG. 4 for the convenience of illustration, and show the structure of these individual devices 80 in a simplified manner. Referring to FIGS. 5A and 5B, arrows c, m and a denote the c-axis direction, the m-axis direction and the a-axis direction respectively.

In order to cleave the wafer 5 into the individual devices 80a and 80b, the individual devices 80a and 80b (the wafer 5) are first adhered to a support sheet 8, as shown in FIG. 5A. This support sheet 8 is an adhesive sheet for preventing the individual devices 80a and 80b from scattering when the wafer 5 is cleaved into the individual devices 80a and 80b. Prior to adhering the wafer 5 to the support sheet 8, the substrate 1 may be mechanically and chemically polished from the rear side in order to reduce the total thickness of the substrate 1 and the thickness of the semiconductor laminate layer 2 in the growth direction in the individual device 80.

Then, the individual device 80 is scanned with a laser beam 9. More specifically, the laser beam 9 is applied for scanning along the scribing line 7 orthogonal to the c-axis in the individual device 80.

Examples of a laser unit (not shown) generating the scanning laser beam 9 include a YAG laser and an excimer laser. A lens 23 for controlling the focal point (convergent point) of the laser beam 9 is attached to a laser beam emitting portion of the laser unit (not shown).

Referring to FIG. 5A, the laser unit (not shown) is alternately on-off controlled to intermittently apply the laser beam 9.

On the position scanned with the laser beam 9 (the position where the laser unit is turned on), the laser beam 9 is converged on a prescribed depth in the individual device 80, and multiphoton absorption is generated on the convergent point. The convergent point is scanned within the interior of the individual device 80, whereby working regions 24 are formed in the individual device 80 due to the multiphoton absorption (working region forming step). As hereinabove described, the scanning laser beam 9 is intermittently applied according to this embodiment, whereby a plurality of (four in FIGS. 5A and 5B) working regions 24 are formed in the form of perforations at predetermined intervals along the scanning direction.

The wavelength of the scanning laser beam 9 is 500 nm to 700 nm. Since the laser beam 9 having the wavelength in this range is not absorbed into the individual device 80 made of the group III nitride semiconductor, the laser beam 9 can be efficiently converged in the individual device 80.

The depth of the convergent point of the laser beam 9 (the positions where the working regions 24 are formed) is preferably 10 μm to 60 μm, for example, and more preferably 20 μm to 40 μm from the surface of the individual device 80. When the working regions 24 are formed by adjusting the lens 23 so that the converging point of the laser beam 9 is in this range, stable cleavage into the individual devices 80a and 80b is possible.

The energy of the laser beam 9 is preferably 5.0×10⁹ W/cm² to 2.0×10¹⁰ W/cm², for example, on the convergent point (the working regions 24) of the laser beam 9. When the energy of the laser beam 9 on the convergent point of the laser beam 9 is in this range, the area between the individual devices 80a and 80b can be excellently processed. On the surface of the support sheet 8, the energy of the laser beam 9 is preferably 1.0×10⁷ W/cm² or less, for example. If the laser beam has a high energy (near the same level to the energy on the laser convergent point, for example) on the surface of the support sheet 8, the support sheet 8 is processed by this laser beam and an adhesive of the support sheet 8 adheres to the individual device 80 to cause in deterioration of the device characteristics or the like. When the energy of the laser beam 9 is set to 1.0×10⁷ W/Cm² on the surface of the support sheet 8 as hereinabove described, the support sheet 8 can be prevented from such processing by the laser beam 9. The energy can be set to the illustrated ranges on the respective positions (the laser convergent point and the support sheet 8) by adjusting the position of the lens 23 or controlling the output of the laser unit (not shown), for example.

The working regions 24 are preferably formed to avoid the waveguide 25 in the individual device 80.

According to this embodiment, the working regions 24 are formed in a length of 20 μm, for example, in the scanning direction of the laser beam 9 (the direction parallel to the c-plane) at intervals of 80 μm, for example, between the adjacent working regions 24. In other words, the working regions 24 are formed in a cycle of 100 μm. This cycle can be properly changed by on-off controlling the laser unit (not shown). Thus, the waveguide 25 can be prevented from concentration of the laser beam 9 by changing the cycle for forming the working regions 24 in response to the size of the individual device 80 (the width in the direction parallel to the c-plane).

After the formation of the working regions 24, the individual device 80 is divided into the individual devices 80a and 80b by cleavage, as shown in FIG. 5B (dividing step).

The individual device 80 is cleaved by externally applying stress along the scribing line 7 formed with the working regions 24, thereby generating cracks from the working regions 24. Thus, the individual device 80 is divided into the individual devices 80a and 80b. In other words, the individual device 80 in this embodiment is cleaved after the formation of the working regions 24, without processing such as forming trenches on the surface of the individual device 80 with a laser beam or a diamond cutter, for example. Thus, the +c-axis side end face in the individual device 80a, i.e., the resonance cavity end face 21 (+c-plane) is obtained.

Thereafter working regions 24 are formed and the individual device 80 is cleaved also along the c-plane on the −c-axis side and the a-plane, similarly to the method mentioned above.

Thus, the individual device 80 of the same size as the semiconductor laser diode 70 separated from the wafer 5 is obtained according to the first embodiment. The insulating films mentioned above (not shown) are each formed on the resonance cavity end faces 21 and 22 of the obtained individual device 80, whereby the semiconductor laser diode 70 is obtained as shown in FIG. 1.

According to this embodiment, as hereinabove described, the working regions 24 are formed by applying the laser beam 9 having a wavelength of 500 nm to 700 nm not absorbed into the group III nitride semiconductor (individual device 80), and thereafter cracks are generated from the working regions 24 so that the wafer 5 is divided into each individual device 80. Thus, the individual device 80 divided into the size (chip size) of the semiconductor laser diode 70 is obtained.

As hereinabove described, the working regions 24 are formed in the individual device 80 due to the multiphoton absorption so that deep cracks can be generated from the working regions 24. Particularly when a plurality of small working regions 24 (each having a length of 20 μm, for example) with respect to the width (200 μm to 400 μm, for example) of the resonance cavity end face 21 are formed as shown in FIGS. 5A and 5B, deep cracks can be generated from the small working regions 24. Therefore, the individual device 80 can be stably cleaved along cleavage planes, and excellent cleavage planes can be obtained. In other words, excellent resonance cavity end faces 21 and 22 formed by the cleavage planes can be obtained in cleavage along the c-plane, whereby a high-performance semiconductor laser diode can be implemented.

In cleavage (division) into each individual device 80, the surface of the individual device 80 is not subjected to working such as formation of trenches with a laser beam or a diamond cutter, for example, whereby generation of debris (dust) can be suppressed when the wafer 5 is cleaved into each individual device 80. Further, the method to form the working regions 24 is not to absorb a laser beam into the individual device 80 to work with heat of the absorbed laser beam, but to converge the laser beam 9 having a small energy in the individual device 80 and generate multiphoton absorption to work. Therefore, the individual device 80 can be prevented from a temperature rise. Consequently, the semiconductor laser diode 70 can be prevented from deterioration of the device characteristics. In addition, the shape of the semiconductor laser diode 70 can be stabilized and the yield thereof can be improved, while minimizing damages on the individual device 80.

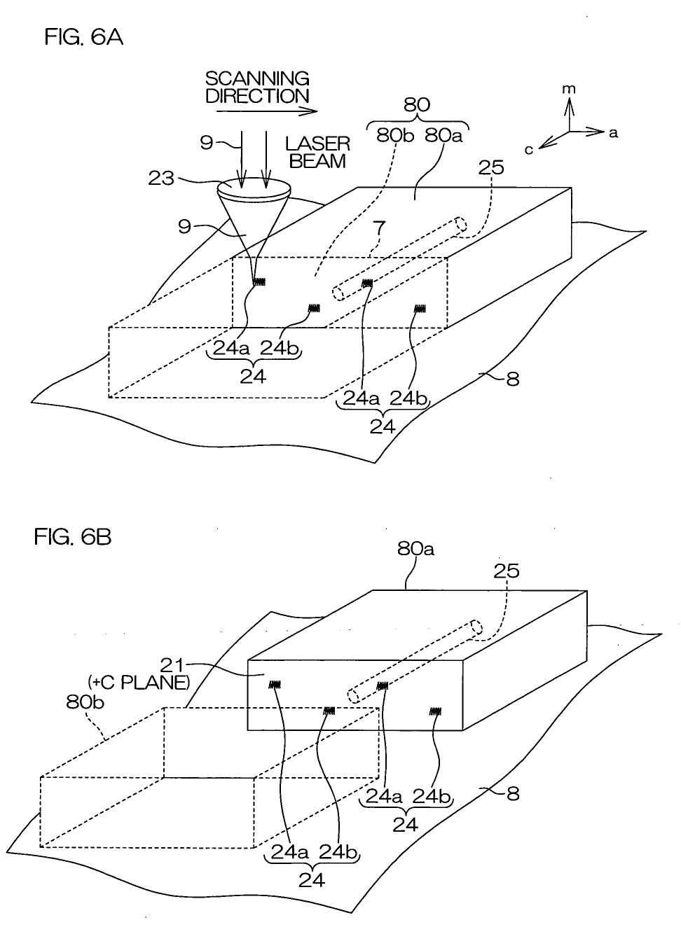

FIGS. 6A and 6B are illustrative diagrams for illustrating a method of cleaving into each individual device 80 according to a second embodiment. FIGS. 6A and 6B illustrate only cleaving into the individual devices 80a and 80b shown in FIG. 4 for the convenience of illustration, and show the structures of these individual devices 80 in a simplified manner, similarly to FIGS. 5A and 5B. Portions corresponding to those shown in FIGS. 5A and 5B are denoted by the same reference numerals.

According to this embodiment, working regions 24a (first working regions) and 24b (second working regions) having different depths from the surface of the individual device 80 are formed, as shown in FIG. 6A.

More specifically, the individual device 80 is scanned with the laser beam 9 twice, and a plurality of (two in FIGS. 6A and 6B) working regions 24a (each having a length of 50 μm, for example) are formed on positions having a depth of 30 μm, for example, from the surface of the individual device 80 at an interval of 400 μm, for example, in the scanning direction in the first scanning.

In the second scanning, the laser beam 9 is applied in the same scanning direction as that in the first scanning, for example, and the working regions 24b (each having a length of 50 μm, for example) are formed on positions having a depth of 40 μm, for example, from the surface of the individual device 80. A plurality of (two in FIGS. 6A and 6B) such working regions 24b are formed on positions displaced from the working regions 24a by 200 μm, for example, from the working regions 24a in the scanning direction of the laser beam 9 (parallel to the c-plane) at an interval of 400 μm, for example. Thus, the working regions 24a and 24b are formed having different depths from the surface of the individual device 80. The remaining conditions (the wavelength of the laser beam 9, the energy of the laser beam 9 on each position or the like) are similar to those in the first embodiment.

After the formation of the working regions 24a and 24b, the individual device 80 is cleaved as shown in FIG. 6B by a method similar to that in FIG. 5B. Thus, the +c-axis side end face in the individual device 80a, i.e., the resonance cavity end face 21 (+c-plane) is obtained.

Thereafter working regions 24 are formed and the individual device 80 is cleaved also along the c-plane on the −c axis side and the a-plane, similarly to the method mentioned above. Thus, the individual device 80 of the same size as the semiconductor laser diode 70 separated from the wafer 5 is obtained according to the second embodiment.

According to this embodiment, as hereinabove described, the working regions 24a and 24b having different depths from the surface of the individual device 80 are formed in the individual device 80.

For example, the refractive index of GaN with respect to light having a wavelength of 500 nm to 700 nm is 252. If the individual device 80 includes a thickness deviation of 4 μm between two arbitrary points and a laser beam is converged on the two points under the same conditions (to use the lens 23 of the same focal length, for example), an error of 10 μm is caused between the depths of working regions formed on the one point and the other.

According to the method to converge the laser beam in the individual device 80 as in this embodiment, stability of cleavage varies with the depths of the working regions 24, so that the depths of the working regions 24 must be precisely controlled. If the individual device 80 is uneven in thickness, it is difficult to precisely control the depths of the working regions 24.

Even if the individual device 80 is uneven in thickness or bent, however, the wafer 5 can be stably cleaved into each individual device 80 when either the working regions 24a or the working regions 24b are formed in a depth optimum for cleaving into each individual device 80 as in this embodiment.

While two types of working regions 24 such as the working regions 24a and 24b having different depths are formed in this embodiment, three or more types of working regions 24 having different depths may be formed, for example. While the scanning direction of the laser beam 9 for forming the working regions 24b is identical that of the laser beam 9 for forming the working regions 24a, direction may be selected as the opposite direction.

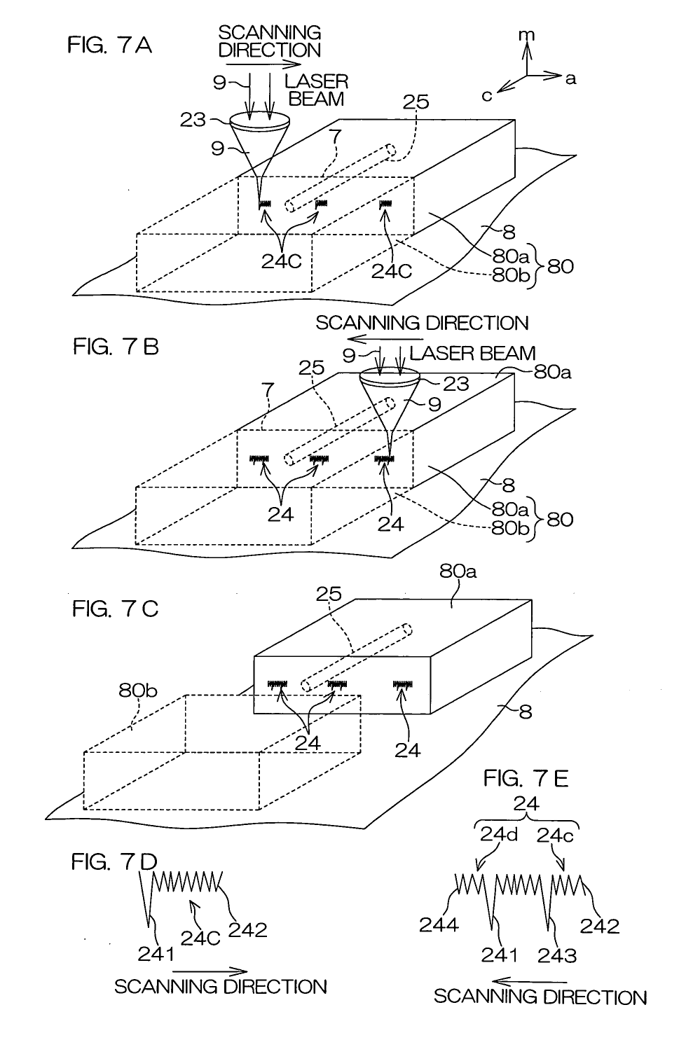

FIGS. 7A to 7E are illustrative diagrams for illustrating a method of cleaving into each individual device 80 according to a third embodiment. FIG. 7D is an enlarged view of a working region 24c shown in FIG. 7A, and FIG. 7E is an enlarged view of a working region 24 shown in FIGS. 7B and 7C. FIGS. 7A to 7E illustrate only a step of cleaving into the individual devices 80a and 80b shown in FIG. 4 for the convenience of illustration, and show the structures of these individual devices 80 in a simplified manner, similarly to FIGS. 5A and 5B. Portions corresponding to those shown in FIGS. 5A and 5B are denoted by the same reference numerals.

According to this embodiment, working regions 24c and 24d overlap each other to form a composite working region 24.

More specifically, the individual device 80 is scanned with the laser beam 9 for forming a plurality of (three in FIGS. 7A to 7C) working regions 24c (each having a length of 20 μm, for example) as shown in FIGS. 7A and 7D by a method similar to that in FIG. 5A. In each working region 24c, a point where working is started (scanning with the laser beam 9 is started) is referred to as a working start position 241 and a point where the working is ended (scanning with the laser beam 9 is ended) is referred to as a working end position 242.

From another working start position 243 (second working start position) located on an intermediate portion between the working start position 241 and the working end position 242 of the working region 24c, i.e., a position where the working region 24c is formed (excluding the working start position 241 and the working end position 242) in a direction parallel to the c-plane in the same depth as the working region 24c in the depth direction of the individual device 80, the scanning laser beam 9 is applied to trace the working region 24c in a direction opposite to the scanning direction for forming the working region 24c (on the same scanning line) to form the working region 24d, as shown in FIGS. 7B and 7E.

The laser beam 9 is so applied that at least a working end position 244 of the working region 24d does not overlap the working region 24c. Thus, the working start position 241 of the working region 24c is enclosed with the working region 24d and the working start position 243 of the working region 24d is enclosed with the working region 24c, whereby the two working regions 24c and 24d form the composite working region 24. The remaining conditions (the wavelength of the laser beam 9, the energy of the laser beam 9 on each position or the like) are similar to those in the first embodiment.

After the formation of the working regions 24c and 24d, the individual device 80 is cleaved as shown in FIG. 7C by a method similar to that in FIG. 5B. Thus, the +c-axis side end face in the individual device 80a, i.e., the resonance cavity end face 21 (+c-plane) is obtained.

Thereafter working regions 24 are formed and the individual device 80 is cleaved also along the c-plane on the −c-axis side and the a-plane, similarly to the method mentioned above. Thus, the individual device 80 of the same size as the semiconductor laser diode 70 separated from the wafer 5 is obtained according to the third embodiment.

According to this embodiment, as hereinabove described, the working start position 241 of the working region 24c is enclosed with the working region 24d and the working start position 243 of the working region 24d is enclosed with the working region 24c, whereby the two working regions 24c and 24d form the composite working region 24.

For example, the output of the laser unit (not shown) emitting the laser beam 9 may not be stable when the laser unit emits the laser beam 9. In other words, stable working may not be performed on a scanning start position of the laser beam 9. On the other hand, the output of the laser unit (not shown) is thereafter stabilized, to perform stable working. Therefore, only the working start positions 241 and 243 of the working regions 24c and 24d are deeply worked, as shown in FIGS. 7D and 7E. If only one of the working regions is formed, it may not be possible to preferably cleave the individual device 80 along the plane formed with the working region.

When the working start positions 241 and 243 are enclosed with the working regions 24c and 24d (stably worked portions) as in this embodiment, however, deeply worked portions can be compensated with stable working, whereby the individual device 80 can be stably cleaved.

While the working region 24 is formed by composition of the two working regions 24c and 24d in this embodiment, the working region 24 may be formed by composition of three or more working regions, for example, so far as working start positions of the respective working regions are not located on ends of the composite working region 24.

While the three embodiments of the present invention are described, the present invention can be carried out according to still another embodiment.

For example, while each of the embodiments is described with reference to only the semiconductor laser diode, the present invention is also applicable to an LED or a transistor, for example, so far as the device is made of a group III nitride semiconductor.

While the present invention has been described in detail by way of the embodiments thereof, it should be understood that these embodiments are merely illustrative of the technical features of the present invention but not limitative to the invention. The spirit and scope of the present invention are to be limited only by the appended claims.

This application corresponds to Japanese Patent Application No. 2007-082310 filed with the Japanese Patent Office on Mar. 27, 2007, the disclosure of which is incorporated herein by reference.

What is claimed is:

1. A method of manufacturing a nitride semiconductor device, including:
a working region forming step of forming a working region in a group III nitride semiconductor substrate by converging a laser beam having a wavelength of 500 nm to 700 nm in the group III nitride semiconductor substrate and by scanning a convergent point of the laser beam in a prescribed scanning direction in the interior of the group III nitride semiconductor substrate; and
a dividing step of dividing the group III nitride semiconductor substrate by generating a crack from the working region without processing a surface of the group III nitride semiconductor substrate.

2. The method of manufacturing a nitride semiconductor device according to claim 1, wherein the working region forming step includes a step of forming a plurality of working regions at a prescribed interval.

3. The method of manufacturing a nitride semiconductor device according to claim 1, wherein the working region forming step includes a step of forming the working region on a position having a depth of 10 μm or more from the surface of the group III nitride semiconductor substrate.

4. The method of manufacturing a nitride semiconductor device according to claim 2, wherein the working region forming step includes a step of forming the working regions on positions having a depth of 10 μm or more from the surface of the group III nitride semiconductor substrate.

5. The method of manufacturing a nitride semiconductor device according to claim 1, wherein the working region forming step includes the steps of:
forming a first working region on a position having a first depth from the surface of the group III nitride semiconductor substrate; and
forming a second working region on a position having a second depth different from the first depth.

6. The method of manufacturing a nitride semiconductor device according to claim 2, wherein the working region forming step includes the steps of:
forming a first working region on a position having a first depth from the surface of the group III nitride semiconductor substrate; and
forming a second working region on a position having a second depth different from the first depth.

7. The method of manufacturing a nitride semiconductor device according to claim 3, wherein the working region forming step includes the steps of:
forming a first working region on a position having a first depth from the surface of the group III nitride semiconductor substrate; and
forming a second working region on a position having a second depth different from the first depth.

8. The method of manufacturing a nitride semiconductor device according to claim 1, wherein the working region forming step further includes a step of forming at least one working region on a position displaced from the working region in the scanning direction and having a depth different from the depth of the working region from the surface of the group III nitride semiconductor substrate.

9. The method of manufacturing a nitride semiconductor device according to claim 2, wherein the working region forming step further includes a step of forming at least one working region on a position displaced from the working regions in the scanning direction and having a depth different from the depth of the working regions from the surface of the group III nitride semiconductor substrate.

10. The method of manufacturing a nitride semiconductor device according to claim 3, wherein the working region forming step further includes a step of forming at least one working region on a position displaced from the working region in the scanning direction and having a depth different from the depth of the working region from the surface of the group III nitride semiconductor substrate.

11. The method of manufacturing a nitride semiconductor device according to claim 1, wherein the working region forming step includes a step of further forming a working region overlapping a working start position of the working region after forming the working region by scanning the convergent point of the laser beam oppositely to the scanning direction from a second working start position which is an intermediate portion between the working start position and a working end position of the working region.

12. The method of manufacturing a nitride semiconductor device according to claim 2, wherein the working region forming step includes a step of further forming a working region overlapping a working start position of the working region after forming the working region by scanning the convergent point of the laser beam oppositely to the scanning direction from a second working start position which is an intermediate portion between the working start position and a working end position of the working region.

13. The method of manufacturing a nitride semiconductor device according to claim 3, wherein the working region forming step includes a step of further forming a working region overlapping a working start position of the working region after forming the working region by scanning the convergent point of the laser beam oppositely to the scanning direction from a second working start position which is an intermediate portion between the working start position and a working end position of the working region.

14. The method of manufacturing a nitride semiconductor device according to claim 1, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working region by scanning the convergent point of the laser beam in a direction orthogonal to an optical waveguide in the semiconductor laser structure.

15. The method of manufacturing a nitride semiconductor device according to claim 2, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working regions by scanning the convergent point of the laser beam in a direction orthogonal to an optical waveguide in the semiconductor laser structure.

16. The method of manufacturing a nitride semiconductor device according to claim 3, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working region by scanning the convergent point of the laser beam in a direction orthogonal to an optical waveguide in the semiconductor laser structure.

17. The method of manufacturing a nitride semiconductor device according to claim 5, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working region by scanning the convergent point of the laser beam in a direction orthogonal to an optical waveguide in the semiconductor laser structure.

18. The method of manufacturing a nitride semiconductor device according to claim 8, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working region by scanning the convergent point of the laser beam in a direction orthogonal to an optical waveguide in the semiconductor laser structure.

19. The method of manufacturing a nitride semiconductor device according to claim 11, wherein the group III nitride semiconductor substrate has a semiconductor laser structure including a first layer of a first conductivity type, an emission layer laminated on the first layer and a second layer of a second conductivity type different from the first conductivity type laminated on the emission layer, and
the working region forming step includes a step of forming the working region by scanning the convergent point of the laser beam in a direction orthogonal to an optical waveguide in the semiconductor laser structure.
